(19) United States
(12) Patent Application Publication
(10) Pub. No.: US 2009/0302473 A1
(43) Pub. Date: Dec. 10, 2009

(54) SEMICONDUCTOR DEVICE AND MANUFACTURING METHOD THEREOF

(75) Inventors: Junichi SHIBATA, Toyama (JP); Takeshi HARADA, Shiga (JP); Akira UEKI, Osaka (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/539,852

(22) Filed: Aug. 12, 2009

Related U.S. Application Data
(63) Continuation of application No. PCT/JP2008/003783, filed on Dec. 16, 2008.

(30) Foreign Application Priority Data
Feb. 7, 2008 (JP) 2008-027726

(51) Int. Cl. H01L 23/522; H01L 21/768

(52) U.S. Cl. 257/751; 438/618; 257/E23.145; 257/E21.581

(57) ABSTRACT

A semiconductor device includes: a first interlayer insulating film formed over a semiconductor substrate; a plurality of interconnects formed in the first interlayer insulating film; and a via and a dummy via, which are formed in the first interlayer insulating film so as to connect to at least one of the plurality of interconnects. A void is selectively formed between adjacent ones of the interconnects in the first interlayer insulating film. The dummy via is formed under an interconnect which is in contact with the void, so as to connect to the interconnect. The via and the dummy via are surrounded by the first interlayer insulating film with no void interposed therebetween.

### CROSS-REFERENCE TO RELATED APPLICATIONS

This is a continuation of Application PCT/JP2008/003783, filed on Dec. 16, 2008. This Non-provisional application claims priority under 35 U.S.C. 119(a) on Patent Application No. 2008-027726 filed in Japan on Feb. 7, 2008, the entire contents of which are hereby incorporated by reference.

### BACKGROUND

The present invention generally relates to a semiconductor device and a manufacturing method thereof. More particularly, the present invention relates to a semiconductor device having a multilayer interconnect structure, and a manufacturing method thereof.

With recent reduction in size of semiconductor integrated circuit elements, the gap between a plurality of elements of a semiconductor device, and the gap between interconnects connecting the elements to each other have been increasingly reduced. This has caused problems of increasing the capacitance between adjacent interconnects, and thus, reducing a signal transmission speed.

Thus, a method of reducing the capacitance between interconnects by forming a void (an air gap) between adjacent interconnects has been examined, as shown in “A Novel SiO₂-Air Gap low-k Copper Dual Damascene Interconnect,” T Micro electronics, V. Arnal et al., p. 71, 2000, Advance Metallization, and United States Published Patent Application No. 2004/0061231.

A manufacturing method of a semiconductor device as a first conventional example, which is shown in “A Novel SiO₂-Air Gap low-k Copper Dual Damascene Interconnect,” T Micro electronics, V. Arnal et al., p. 71, 2000, Advance Metallization, will be described below with reference to FIGS. 14A through 14D.

First, as shown in FIG. 14A, a first insulating film 10 is deposited over a semiconductor substrate (not shown), and then, a plurality of interconnect grooves 10a are formed in an upper part of the deposited first insulating film 10. Then, a barrier metal film 11 is formed on the bottom and wall surfaces of each interconnect groove 10a in the first insulating film 10, and then, interconnects 12, which are made of copper (Cu), are formed so as to embed the interconnect grooves 10a.

Then, as shown in FIG. 14B, a liner insulating film 13 is deposited over the first insulating film 10 including the interconnects 12, in order to prevent diffusion of Cu of the interconnects 12.

Then, as shown in FIG. 14C, a resist pattern 14 is formed on the liner insulating film 13 by a lithography method. The resist pattern 14 has an opening pattern which enables only the regions between adjacent interconnects 12 in the first insulating film 10 to be removed.

Then, as shown in FIG. 14D, the liner insulating film 13 and the first insulating film 10 are etched by a dry etching method by using the resist pattern 14 as a mask, thereby forming voids (air gaps) 15 between the interconnects 12.

Then, a second insulating film, which has a low coverage ratio and a low embedding property, is deposited over the liner insulating film 13 so as not to embed the voids 15, whereby closed voids 15 are formed.

A multilayer interconnect structure having an arbitrary number of layers is obtained by sequentially repeating the above steps.

In the semiconductor device having multilayer interconnects, providing the air gaps 15 between the copper interconnects 12 in this manner can reduce the capacitance between adjacent interconnects 12.

On the other hand, United States Published Patent Application No. 2004/0061231 describes a semiconductor device shown in FIG. 15, as a second conventional example. In the semiconductor device of FIG. 15, first layer interconnects 30, 31, 32 are formed over a semiconductor substrate (not shown), second layer interconnects 33, 34, 35 are formed over the first layer interconnects 30, 31, 32, and third layer interconnects 36, 37, 38 are formed over the second layer interconnects 33, 34, 35. Vias 40 are formed so as to connect the first layer interconnects 30, 31, 32 and the second layer interconnects 33, 34, 35, and vias 41 are formed so as to connect the second layer interconnects 33, 34, 35 and the third layer interconnects 36, 37, 38. Moreover, dummy vias 42 are formed so as to connect the first layer interconnects 30, 31, 32 and the second layer interconnects 33, 34, 35, and so as to connect the second layer interconnects 33, 34, 35 and the third layer interconnects 36, 37, 38. These interconnects are made of copper, and the dummy vias 42 are made of an insulating material, and do not form an electric circuit. Voids are formed around all of the first through third layer interconnects, the vias, and the dummy vias.

### SUMMARY

However, the semiconductor devices having a multilayer interconnect structure according to the above first and second conventional examples have the following problems.

Problems of the first conventional example will be described below with reference to FIGS. 16 through 18.

FIG. 16 shows a planar structure of a semiconductor device formed by the manufacturing method of the first conventional example. Problems of the manufacturing method of the semiconductor device of the first conventional example will be described by using FIGS. 17A through 17D which correspond to a cross section taken along line XVII-XVII in FIG. 16.

First, as shown in FIG. 17A, a first insulating film 1 is deposited over a semiconductor substrate (not shown), and then, a plurality of interconnect grooves 1a are formed in an upper part of the deposited first insulating film 1. Then, a barrier metal film 4 is formed on the bottom and wall surfaces of the interconnect grooves 1a in the first insulating film 1, and then, interconnects 5, made of copper (Cu), are formed so as to embed the interconnect grooves 1a.

Then, as shown in FIG. 17B, a liner insulating film 7 is deposited over the first insulating film 1 including the interconnects 5, in order to prevent diffusion of Cu of the interconnects 5.

Then, as shown in FIG. 17C, a resist pattern 8 is formed on the liner insulating film 7 by a lithography method. The resist pattern 8 has an opening pattern which enables only the regions between adjacent interconnects 5 in the first insulating film 1 to be removed.

Then, as shown in FIG. 17D, the liner insulating film 7 and the first insulating film 1 are etched by a dry etching method by using the resist pattern 8 as a mask, thereby forming voids (air gaps) 3 between the interconnects 5.

Then, a second insulating film, which has a low coverage ratio and a low embedding property, is deposited over the liner insulating film 7 so as not to embed the voids 3, whereby closed voids 3 are formed.

A multilayer interconnect structure having an arbitrary number of layers is obtained by sequentially repeating the above steps.

In the semiconductor device having multilayer interconnects, providing the air gaps 3 between the copper interconnects 5 in this manner can reduce the capacitance between adjacent interconnects 5.

FIG. 18 is a cross-sectional view taken along line XVIII-XVIII in FIG. 16, and shows a sectional structure corresponding to the step shown in FIG. 17D. Note that FIG. 16 shows a planar structure in a cross section taken along line XVI-XVI in FIG. 18.

In the first conventional example, in the step shown in FIG. 17A, a damage layer 1A is formed at the bottom of each interconnect groove 1a in the first insulating film 1 during formation of the interconnect grooves 1a, and during formation of the barrier metal 4. In the case where carbon-added silicon oxide (SiOC) is used as the first insulating film 1, a SiOₓ layer is formed as the damage layer 1A. Note that such a damage layer 1A is generated similarly when a SiOC film having pores introduced therein, an organic insulating film such as SiLK (registered trademark), FLARE (registered trademark), fluoro-silicate glass (FSG), polyimide, or benzo-cyclo-butene (BCB), fluoro-hydrocarbon, or the like is used as the first insulating film 1.

Moreover, as shown in FIG. 17D, the portions located under the interconnects 5 in the first insulating film 1 are partially recessed by the etching process for forming the voids 3. Thus, since the damage layer 1A has been formed also in a portion, which is located under the interconnect 5 having both side surfaces in contact with the void 3, this interconnect 5, which has a recessed portion thereunder, peels off from the first insulating film 1, and the damage layer 1A formed in the portion under this interconnect 5 acts as a base point of the peeling-off, as shown in FIG. 19. As a result, the interconnect 5 disappears, reducing the yield of the semiconductor devices.

As can be seen also from FIG. 18, in a bent portion 5b of the interconnect 5, the portion located under the interconnect 5 is more easily etched in its outer periphery than in its inner periphery. Thus, the interconnect 5 tends to peel off from the first insulating film 1 in the bent portion 5b of the interconnect 5.

Moreover, in the second conventional example, voids are formed not only between the interconnects, but also around the vias and the dummy vias, causing a problem of reduced mechanical strength.

Note that the present invention need not necessarily solve all the problems described above, but need only solve at least one of these problems.

In view of the above problems, it is an object of the present invention to achieve a high yield, to sufficiently reduce the capacitance between interconnects, and to obtain sufficient mechanical strength.

Note that the present invention need not necessarily achieve all the objects described above, but need only achieve at least one of these objects.

In order to achieve the above objects, according to the present invention, an interconnect structure of a semiconductor device is configured so that a dummy via is formed under an interconnect which has a void to be formed on both sides, and the dummy via is connected to the interconnect.

More specifically, a semiconductor device according to the present invention includes: an insulating film formed over a semiconductor substrate; a plurality of interconnects formed in the insulating film; a via formed in the insulating film so as to connect to at least one of the plurality of interconnects; and a dummy via formed in the insulating film so as to connect to at least one of the plurality of interconnects. A void is selectively formed between adjacent ones of the interconnects in the insulating film. The dummy via is formed under an interconnect which is in contact with the void, so as to connect to the interconnect. The via and the dummy via are surrounded by the insulating film with no void interposed therebetween.

According to the present invention, the semiconductor device includes a dummy via formed in the insulating film so as to connect to at least one of the plurality of interconnects, a void is selectively formed between adjacent ones of the interconnects in the insulating film, the dummy via is formed under an interconnect which is in contact with the void, so as to connect to the interconnect, and the via and the dummy via are surrounded by the insulating film with no void interposed therebetween. That is, the dummy via, formed under the interconnect which is in contact with the void, so as to connect to the interconnect, is directly surrounded by the insulating film. Because of the dummy via, a portion in the insulating film, which is located under the interconnect in contact with the void, is not recessed when forming the void. As a result, the interconnect, which is in contact with the void on its both surfaces, can be prevented from peeling off from the insulating film. Moreover, since the via and the dummy via are surrounded by the insulating film with no void interposed therebetween, a semiconductor device, having high mechanical strength and low capacitance between interconnects, can be obtained.

In the semiconductor device of the present invention, it is preferable that a height of a bottom surface of the void from the semiconductor substrate be lower than, or equal to, that of a bottom surface of the interconnect which is in contact with the void.

In the semiconductor device of the present invention, it is preferable that a width of the interconnect which is in contact with the void be larger than that of an interconnect which is not in contact with the void.

In the semiconductor device of the present invention, it is preferable that the interconnect which is in contact with the void have its peripheral surface entirely in contact with the void.

Moreover, in the semiconductor device of the present invention, it is preferable that the interconnect which is in contact with the void have its peripheral surface discontinuously in contact with the void.

In the semiconductor device of the present invention, it is preferable that the dummy via be formed so as to connect to an interconnect having a smallest interconnect width among the plurality of interconnects.

In the semiconductor device of the present invention, it is preferable that multiple ones of the dummy via be formed in one of the plurality of interconnects.

In the semiconductor device of the present invention, it is preferable that the dummy via be formed between two of the via, which are formed spaced apart from each other in one of the plurality of interconnects, so as to have a length substantially corresponding to a gap between the two of the via along the one interconnect.

In the semiconductor device of the present invention, it is preferable that the plurality of interconnects have a bent portion which is bent in a direction parallel to the semiconductor substrate, and that the dummy via be formed so as to connect to the bent portion.

In the semiconductor device of the present invention, it is preferable that a lower-layer insulating film be formed under the dummy via, and that the dummy via be connected to the lower-layer insulating film.

In the semiconductor device of the present invention, it is preferable that a concavo-convex portion be formed on a side surface of the dummy via, and that a level of concaves and convexes of the concavo-convex portion of the dummy via be larger than that of concaves and convexes of a concavo-convex portion formed on a side surface of the via.

In the semiconductor device of the present invention, it is preferable that the dummy via have a larger diameter in its lower end than in its upper end.

In the semiconductor device of the present invention, it is preferable that the insulating film be a SiOC film.

In the semiconductor device of the present invention, it is preferable that the insulating film be a laminated film of a first insulating film and a second insulating film, that the dummy via and the via be formed in the first insulating film, and that the interconnects be formed in the second insulating film.

In this case, it is preferable that the first insulating film be an insulating film having higher mechanical strength than that of the second insulating film.

Moreover, in this case, it is preferable that the first insulating film be an insulating film having a lower pore ratio than that of the second insulating film.

Moreover, in this case, it is preferable that the second insulating film be a SiOC film.

Moreover, it is preferable that the first insulating film be a film containing silicon oxide, or a film containing silicon nitride.

In the semiconductor device of the present invention, it is preferable that the via be connected to an interconnect which is not in contact with the void, among the plurality of interconnects.

It is preferable that the semiconductor device of the present invention further include a liner film formed over the insulating film so as to be in contact with the insulating film, for preventing diffusion of a metal of the interconnects.

In this case, it is preferable that the liner film be a film containing SiCN.

It is preferable that the semiconductor device of the present invention further include a cap film formed on the plurality of interconnects so as to be in contact with the interconnects, for preventing current leakage from the interconnects.

In this case, it is preferable that the cap film be made of Co, Mn, W, Ta, or Ru, or an alloy containing at least one kind of a metal selected from Co, Mn, W, Ta, and Ru, or an oxide of Co, Mn, W, Ta, or Ru, or CuSiN, and that the cap film have a conductive property.

A method for manufacturing a semiconductor device includes the steps of: (a) forming a first insulating film over a semiconductor substrate; (b) forming a dummy via hole, a via hole, and a plurality of interconnect grooves connecting to the dummy via hole and the via hole, in the first insulating film; (c) embedding a conductive film in the plurality of interconnect grooves, the via hole, and the dummy via hole to form a plurality of interconnects, a via, and a dummy via from the conductive film; (d) selectively removing a region between the interconnects in the first insulating film to form a void between the interconnects; and (e) forming a second insulating film over the first insulating film so as to cover the plurality of interconnects and the void. The dummy via is formed so as to connect to an interconnect which is in contact with the void, and the via and the dummy via are surrounded by the first insulating film with no void interposed therebetween.

According to the manufacturing method of the semiconductor device of the present invention, the dummy via is formed so as to connect only to an interconnect which is in contact with the void, and the via and the dummy via are surrounded by the first insulating film with no void interposed therebetween. Because of the dummy via, a portion in the insulating film, which is located under the interconnect in contact with the void, is not recessed when forming the void. As a result, the interconnect, which is in contact with the void on its both surfaces, can be prevented from peeling off from the insulating film. Moreover, since the via and the dummy via are surrounded by the insulating film, a semiconductor device, having high mechanical strength and low capacitance between interconnects, can be obtained.

In the manufacturing method of the semiconductor device of the present invention, it is preferable that, in the step (d), the void be formed so that a height of a bottom surface of the void from the semiconductor substrate becomes lower than that of bottom surfaces of the interconnects.

In the manufacturing method of the semiconductor device of the present invention, it is preferable that, in the step (d), the interconnects be formed so that a width of the interconnect which is in contact with the void is larger than that of an interconnect which is not in contact with the void.

In the manufacturing method of the semiconductor device of the present invention, it is preferable that, in the step (d), the void be formed entirely around an interconnect for which the void is to be formed.

Moreover, in the manufacturing method of the semiconductor device of the present invention, it is preferable that, in the step (d), the void be formed discontinuously around an interconnect for which the void is to be formed.

In the manufacturing method of the semiconductor device of the present invention, it is preferable that, in the step (c), the dummy via be formed so as to connect to an interconnect having a smallest interconnect width among the plurality of interconnects.

In the manufacturing method of the semiconductor device of the present invention, it is preferable that, in the step (c), multiple ones of the dummy via be formed in one of the plurality of interconnects.

In the manufacturing method of the semiconductor device of the present invention, it is preferable that, in the step (c), the dummy via is formed between two of the via, which are formed spaced apart from each other in one of the plurality of interconnects, so as to have a length substantially corresponding to a gap between the two of the via along the one interconnect.

In the manufacturing method of the semiconductor device of the present invention, it is preferable that, in the step (c), the dummy via be formed so as to connect to a bent portion of the interconnects, which is bent in a direction parallel to the semiconductor substrate.

In the manufacturing method of the semiconductor device of the present invention, it is preferable that, in the step (b), the dummy via hole be formed by an isotropic etching process.

In the semiconductor device and the manufacturing method thereof according to the present invention, a dummy via is formed under an interconnect which is in contact with a void, so as to connect to the interconnect. This can prevent the interconnect from peeling off from an insulating film, and also, can provide a semiconductor device having high mechanical strength and low capacitance between the interconnects.

### BRIEF DESCRIPTION OF THE DRAWINGS

FIG. 1 is a plan view taken along line I-I in FIGS. 2, 3, and 9, showing a semiconductor device according to a first example embodiment.

FIG. 2 is a cross-sectional view taken along line II-II in FIG. 1, showing the semiconductor device according to the first example embodiment.

FIG. 3 is a cross-sectional view showing a semiconductor device according to a first modification of the first example embodiment.

FIG. 4 is a cross-sectional view of a dummy via according to a first modification of the semiconductor device of the first example embodiment.

FIG. 5 is a cross-sectional view of a dummy via according to a second modification of the semiconductor device of the first example embodiment.

FIG. 6 is a cross-sectional view showing a semiconductor device according to a second modification of the first example embodiment.

FIG. 7 is a cross-sectional view showing a semiconductor device according to a third modification of the first example embodiment.

FIG. 8 is a cross-sectional view showing a semiconductor device according to a fourth modification of the first example embodiment.

FIG. 9 is a cross-sectional view taken along line IX-IX in FIG. 1, showing a sectional structure in a bent portion of an interconnect of the semiconductor device according to the first example embodiment.

FIGS. 10A, 10B, 10C, 10D, and 10E are step-by-step cross-sectional views illustrating a manufacturing method of the semiconductor device according to the first example embodiment.

FIGS. 11A, 11B, and 11C are step-by-step cross-sectional views illustrating the manufacturing method of the semiconductor device according to the first example embodiment.

FIG. 12 is a cross-sectional view corresponding to line II-II in FIG. 1, showing a semiconductor device according to a second example embodiment.

FIGS. 13A, 13B, 13C, and 13D are step-by-step cross-sectional views illustrating a main part of a manufacturing method of the semiconductor device according to the second example embodiment.

FIGS. 14A, 14B, 14C, and 14D are step-by-step cross-sectional views illustrating a main part of a manufacturing method of a semiconductor device according to a first conventional example.

FIG. 15 is a bird's eye view showing a multilayer interconnect structure of a semiconductor device according to a second conventional example.

FIG. 16 is a plan view taken along line XVI-XVI in FIG. 18, showing problems of a semiconductor device formed by the manufacturing method of the semiconductor device of the first conventional example.

FIGS. 17A, 17B, 17C, and 17D are step-by-step cross-sectional views illustrating problems of the manufacturing method of the semiconductor device of the first conventional example.

FIG. 18 is a cross-sectional view taken along line XVIII-XVIII in FIG. 16, showing a sectional structure for illustrating problems which occur in a bent portion of an interconnect of the semiconductor device formed by the manufacturing method of the semiconductor device of the first conventional example.

FIG. 19 is a cross-sectional view illustrating problems in the manufacturing method of the semiconductor device of the first conventional example.

### DETAILED DESCRIPTION

### First Example Embodiment

A first example embodiment will be described with reference to the accompanying drawings.

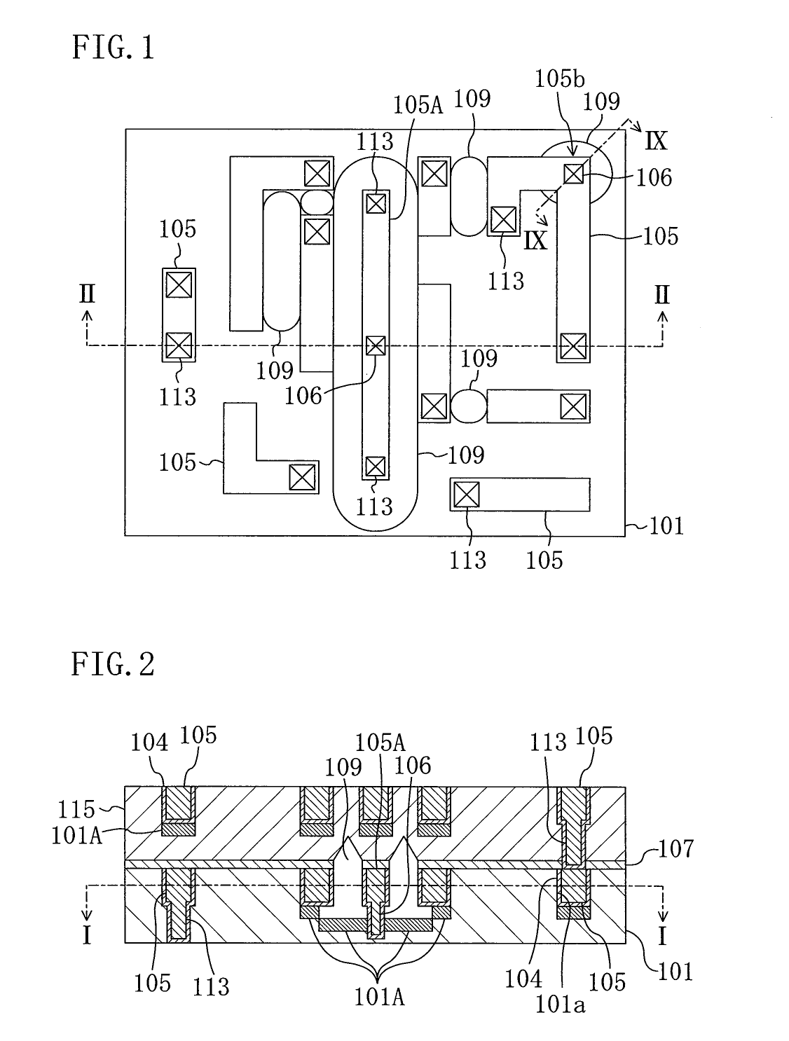

FIGS. 1 and 2 show a semiconductor device according to the first example embodiment, where FIG. 1 shows a planar structure along line I-I in FIG. 2, and FIG. 2 shows a sectional structure along line II-II in FIG. 1.

As shown in FIGS. 1 and 2, a plurality of interconnects 105, 105A are formed spaced apart from each other in an upper part of a first interlayer insulating film 101 formed over a semiconductor substrate (not shown). Voids (air gaps) 109 are selectively formed between adjacent interconnects 105, 105A in the first interlayer insulating film 101. A via 113, which is electrically connected to other interconnect layer, is formed in at least one end of each interconnect 105, 105A. The interconnects 105, 105A are made of, for example, copper (Cu), and are formed inside a barrier metal film 104, which is formed on the bottom and wall surfaces of interconnect grooves 101a formed in the first interlayer insulating film 101. Note that a laminated film, which is formed by sequentially laminating, for example, tantalum (Ta) and tantalum nitride (TaN) in this order, can be used as the barrier metal film 104.

A second interlayer insulating film 115, having interconnects 105 and vias 113 formed therein, is formed over the first interlayer insulating film 101 with a liner insulating film 107 interposed therebetween. The liner insulating film 107 is formed in order to prevent diffusion of Cu atoms of the interconnects 105, 105A, and for example, SiCN can be used as the linear insulating film 107.

As a feature of the present disclosure, a dummy via 106 is formed under each interconnect 105A having a void 109 formed around its entire periphery, and a dummy via 106 is formed also under a bent portion 105b of each interconnect 105 having the bent portion 105b and having a void 109 formed around the bent portion 105b. A lower end of each dummy via 106 is not connected to an interconnect in a lower layer, but is terminated at an intermediate position in the first interlayer insulating film 101 or the liner insulating film 107. In other words, the lower end of each dummy via 106 is in contact with the insulating film. However, the dummy vias 106 may be connected to any interconnects which do not form a circuit, such as dummy lower-layer interconnects (dummy interconnects). The term “dummy via” herein refers to a via which does not form a circuit.

As shown in FIG. 2, in the first interlayer insulating film 101, a damage layer 101A is formed in the portions, which are located under the interconnects 105 and have no via 113 formed therein. As described above, the damage layer 101A is formed in the first insulating film 101 during formation of the interconnect grooves 101a, and during formation of the barrier metal film 104.

However, since the dummy via 106 is formed under the interconnect 105A whose side surfaces are mostly in contact with the void 109, no damage layer 101A is formed in the portion where the dummy via 106 is formed.

Moreover, since the dummy via 106 is formed under the interconnect 105A, the damage layer 101A is not recessed in the region where the dummy via 106 is formed, as compared to the case where no dummy via 106 is formed under the interconnect 105A. In addition, the dummy via 106 is structured like a stake driven into the first interlayer insulating film 101. Thus, friction is generated between the dummy via 106 and the first interlayer insulating film 101 even if the width of a portion where no dummy via 106 is formed in the interconnect 105A is small, and the damage layer 101A has been recessed to some degree.

For the above two reasons, the interconnect 105A, whose periphery is almost entirely in contact with the void 109, is less likely to peel off from the first interlayer insulating film 101. Moreover, the voids 109 are formed so that the height of the bottom surfaces of the voids 109 from the semiconductor substrate is equal to, or lower than, that of the bottom surfaces of the interconnects 105, 105A. Thus, the capacitance between the interconnects 105, 105A is further reduced especially when the bottom surfaces of the voids 109 are located lower than the bottom surfaces of the interconnects 105, 105A.

Moreover, in the first interlayer insulating film 101, no void 109 is formed in the regions where the via 113 and the dummy via 106 are formed (however, there exists a portion partially etched by forming the void 109), and in the regions where the gap between the interconnects 105 is relatively large. This ensures the mechanical strength of the first interlayer insulating film 101.

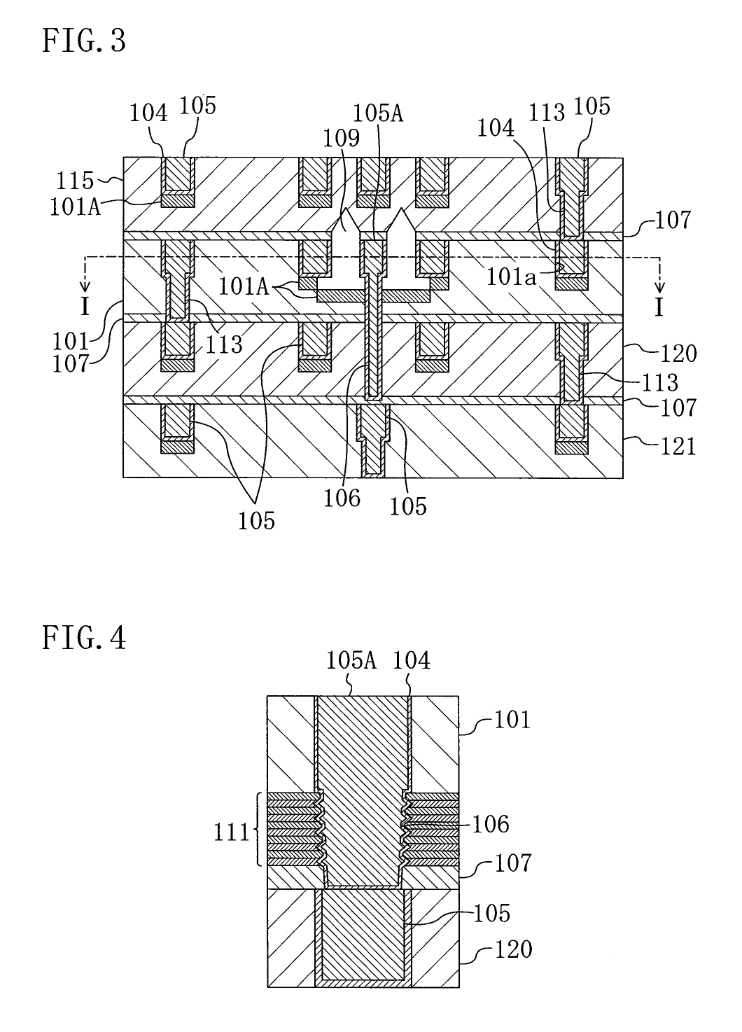

FIG. 3 shows a sectional structure of a semiconductor device according to a first modification of the first example embodiment. As shown in FIG. 3, a dummy via 106, which is connected to the bottom of the interconnect 105A having a void 109 formed almost entirely around its periphery, extends through a first lower-layer interlayer insulating film 120 formed under a first interlayer insulating film 101, and a lower end of the dummy via 106 reaches an intermediate position in a liner insulating film 107, which is formed on an interconnect 105 formed in a second lower-layer interlayer insulating film 121 located under the first lower-layer interlayer insulating film 120. As described above, however, the dummy via 106 can be directly connected to the interconnect 105 if the interconnect 105 is a dummy lower-layer interconnect (a dummy interconnect) which does not form a circuit. Thus, the dummy via 106 having a larger depth is more preferable. This is because the frictional force between the dummy via 106 and each interlayer insulating film 101, 120 increases as the depth of the dummy via 106 increases. Thus, the interconnect 105A can be more reliably prevented from peeling off from the first interlayer insulating film 101, as compared to the case where the height dimension of the dummy via 106 is small enough that the dummy via 106 does not extend through the first interlayer insulating film 101.

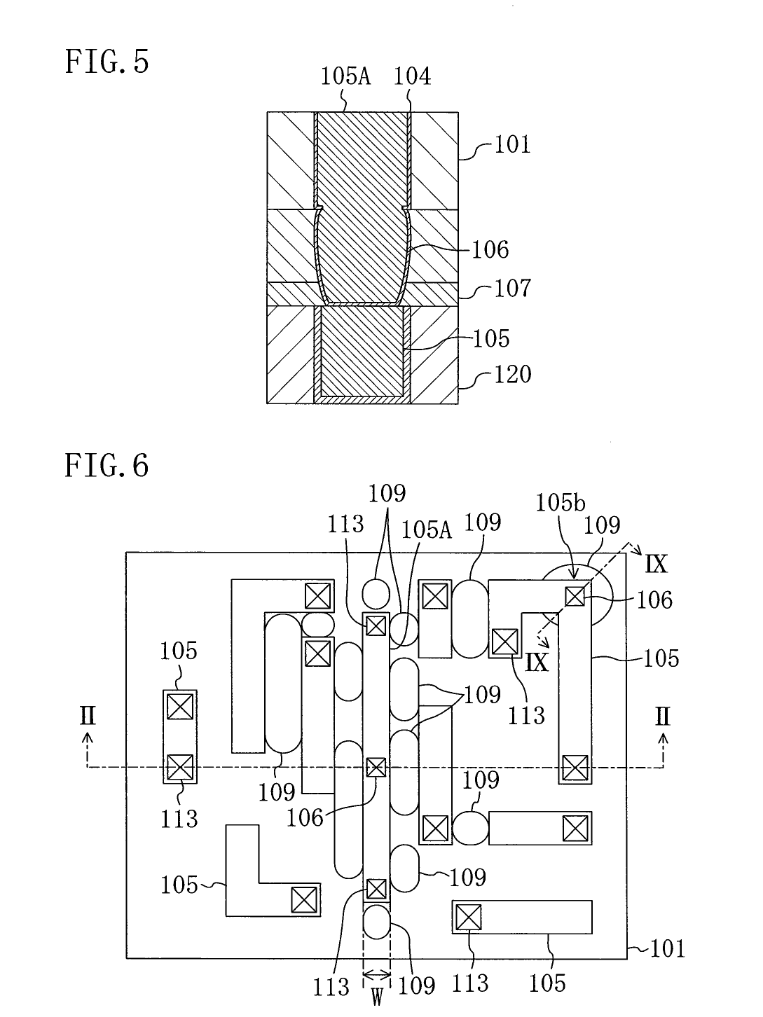

FIGS. 4 and 5 show modifications of the dummy via 106. As shown in a first modification of FIG. 4, the dummy via 106 preferably have a concavo-convex shape on its side surface. Regarding the concavo-convex shape formed on the side surface of the dummy via 106, the larger the level of concaves and convexes is, the more preferable. For example, the level of concaves and convexes of the concavo-convex shape is preferably larger than the level of concaves and convexes produced when forming the interconnect grooves 101a. In other words, the larger the roughness of the side surface of the dummy via 106 is, the more preferable.

Moreover, as shown in FIG. 5, it is preferable that the dummy via 106 have a smaller diameter in its lower and upper ends than in its intermediate part. In other words, it is preferable that the dummy via 106 be shaped so that the distance from the center of the via to the outer peripheral surface thereof, when the dummy via 106 is viewed from above, increases from the upper end of the dummy via 106 toward the intermediate part thereof, and decreases from the intermediate part to the lower end of the dummy via 106.

Thus, forming the dummy via 106 in the shape shown in FIG. 4 or 5 increases the frictional force between the dummy via 106 and the first interlayer insulating film 101. This can more reliably prevents the interconnect 105A from peeling off from the first interlayer insulating film 101.

FIG. 6 shows a planar structure of a semiconductor device according to a second modification of the first example embodiment. As shown in FIG. 6, it is desirable to form a dummy via 106 under the interconnect 105A even when a void 109 is formed partially around the interconnect 105A. This is because, especially when an interconnect width W is small, the interconnect 105A can peel off from the first interlayer insulating film 101 even if the void 109 is formed partially around the interconnect 105A.

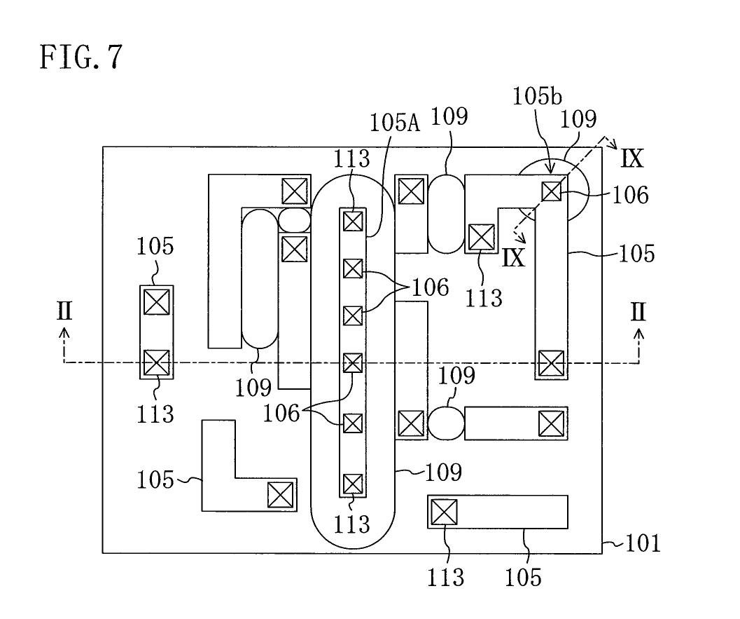

FIG. 7 shows a planar structure of a semiconductor device according to a third modification of the first example embodiment. As shown in FIG. 7, in the semiconductor device of the third modification, it is preferable to form a plurality of dummy vias 106 under the interconnect 105A in the case where a void 109 is formed entirely around the interconnect 105A. This can more reliably prevent the interconnect 105A from peeling off from the first interlayer insulating film 101.

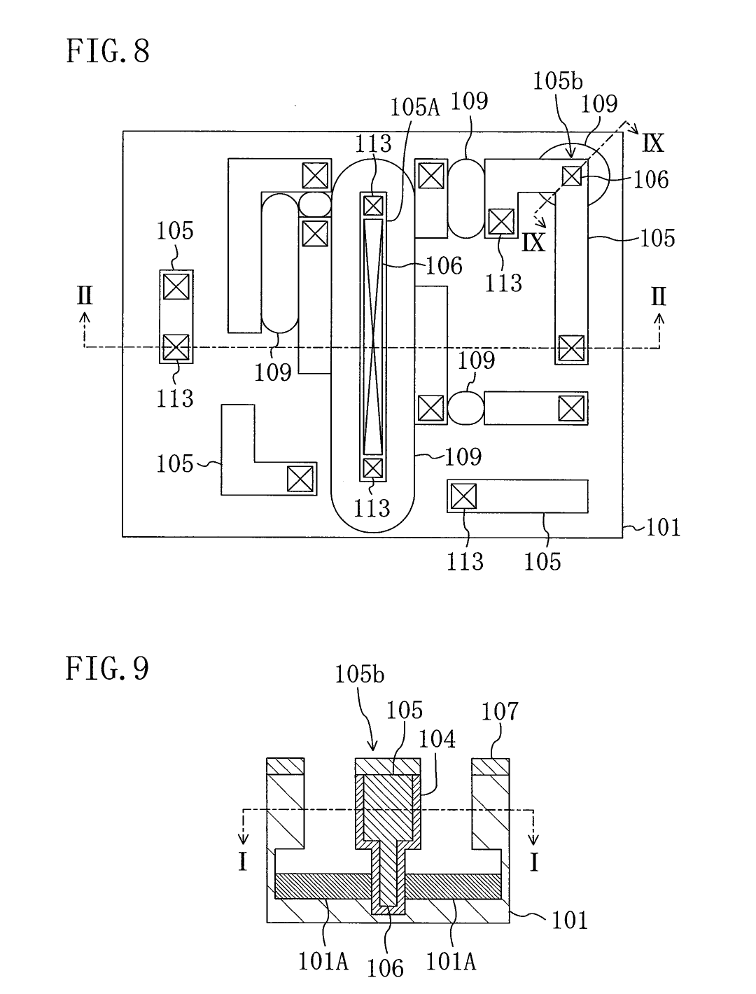

FIG. 8 shows a planar structure of a semiconductor device according to a fourth modification of the first example embodiment. As shown in FIG. 8, in the case where a void 109 is formed entirely around the interconnect 105A, it is preferable that one dummy via 106 be formed between two vias 113, formed at both ends of the interconnect 105A, so as to have a length substantially corresponding to the gap between the two vias 113 along the interconnect 105A. This can more reliably prevent the interconnect 105A from peeling off from the first interlayer insulating film 101.

FIG. 9 shows a sectional structure along line IX-IX in FIGS. 1, 6, 7, and 8. As shown in FIG. 9, it is preferable to form a dummy via 106 in a bent portion 105b where an interconnect 105 is bent in a direction parallel to the semiconductor substrate. It can be seen from the figure that, in the bent portion 105b, the portion located under the interconnect 105 in the first interlayer insulating film 101 is not recessed in the region where the dummy via 106 is provided.

As described above, the portion under the interconnect 105 in the first interlayer insulating film 101 tends to be recessed to a larger degree in the bent portion 105b of the interconnect 105. Thus, providing the dummy via 106 in the bent portion 105b of the interconnect 105, as described in the first example embodiment, can more reliably prevent the interconnect 105 having the bent portion 105b from peeling off from the first interlayer insulating film 101.

Moreover, it is preferable that the interconnect 105A, having a void 109 formed entirely around its periphery, have a large interconnect width. That is, it is preferable that the interconnect 105A, which has a void 109 formed entirely around its periphery, have a larger interconnect width than that of the interconnect 105, which has no void 109 formed around the most part of its periphery. Increasing the interconnect width to a relatively large value can prevent the portion under the interconnect 105A in the first interlayer insulating film 101 from being recessed when forming the void 109 entirely around the periphery of the interconnect 105A. This can more reliably prevent the interconnect 105A from peeling off from the first interlayer insulating film 101.

The above description applies also to a second example embodiment described below.

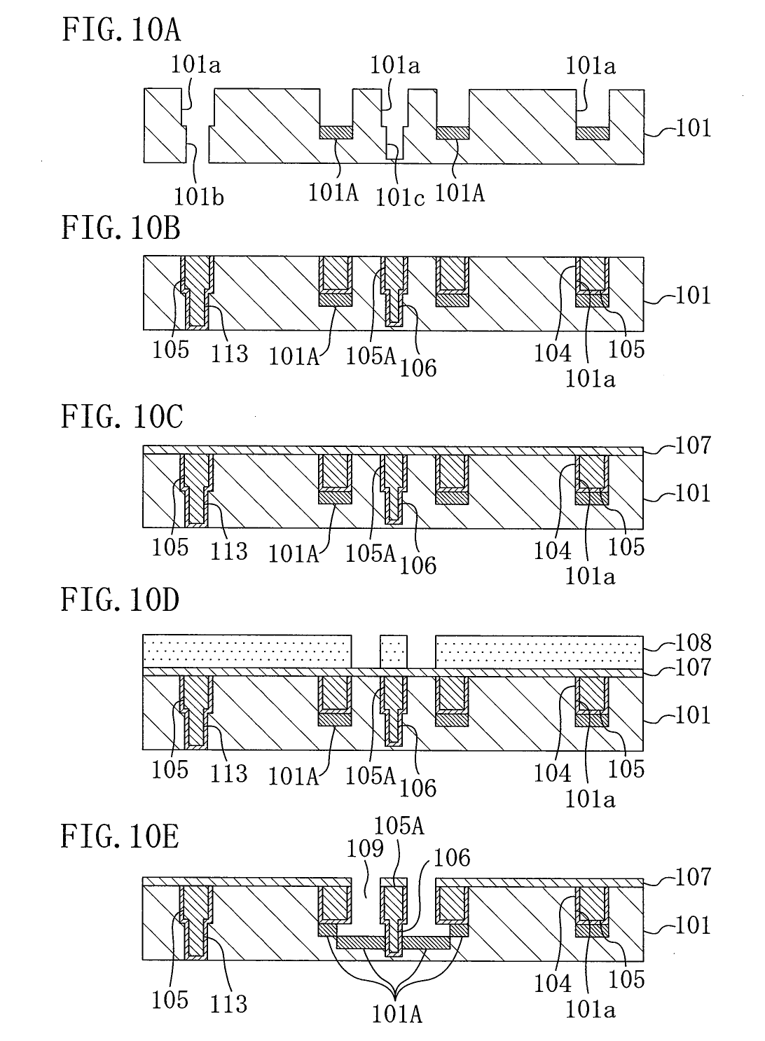

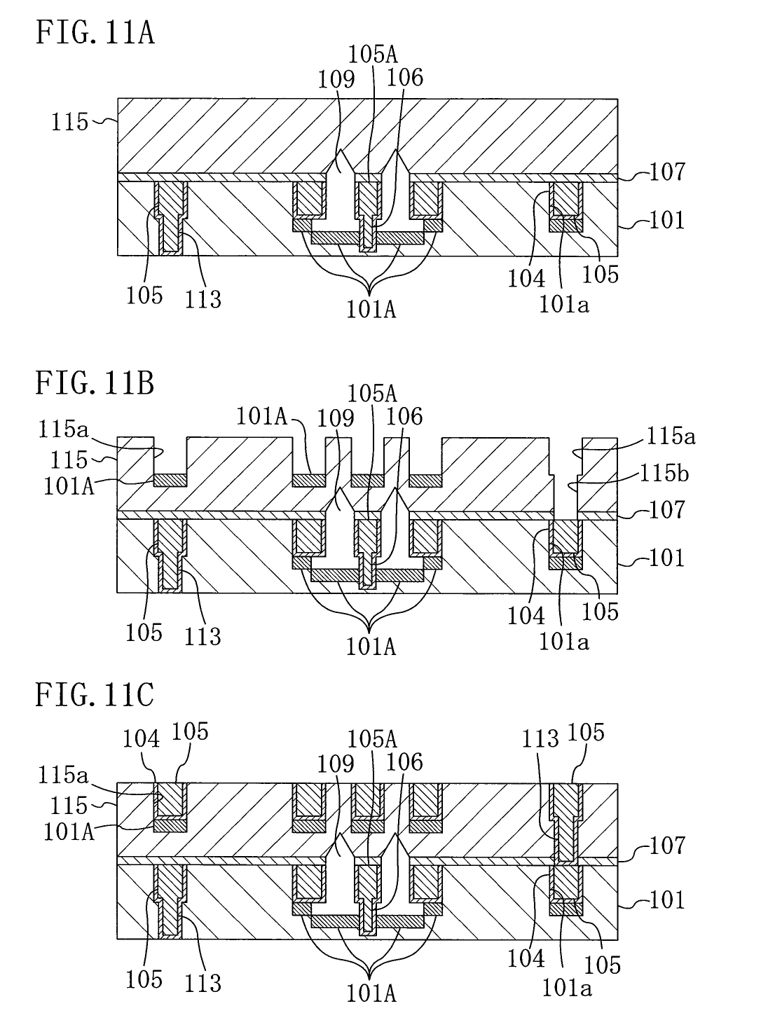

A manufacturing method of the semiconductor device according to the first example embodiment will be described below with reference to FIGS. 10A through 10E and FIGS. 11A through 11C. FIGS. 10A through 10E and FIGS. 11A through 11C illustrate the manufacturing method, step by step, in a cross section corresponding to line II-II in FIG. 1.

First, as shown in FIG. 10A, a first interlayer insulating film 101 is deposited over a semiconductor substrate (not shown). Then, a via hole 101b and a dummy via hole 101c are formed in the first interlayer insulating film 101 by a lithography method and a dry etching method, and then, first interconnect grooves 101a are selectively formed so as to be connected to the via hole 101b or the dummy via hole 101c. The dummy via hole 101c is formed so as to connect only to an interconnect 105A, for which a void is to be formed around the most part of its periphery in a later step. It is desirable to use a film having a relatively low dielectric constant, for example, a SiOC film having pores introduced therein, or an organic insulating film such as SiLK (registered trademark), FLARE (registered trademark), FSG, polyimide, or benzo-cyclo-butene (BCB), or fluoro-hydrocarbon, or the like, as the first insulating film 101.

Then, as shown in FIG. 10B, a barrier metal film 104 and a seed layer (not shown) are sequentially formed on the bottom and wall surfaces of the interconnect grooves 101a in the first interlayer insulating film 101, and on the bottom and wall surfaces of the via hole 101b and the dummy via hole 101c. Then, a conductive film, made of copper, is embedded in the interconnect grooves 101a, the via hole 101b, and the dummy via hole 101c, which have the barrier metal film 104 and the seed layer formed thereon. Then, excess copper, remaining on the first interlayer insulating film 101, is removed by a chemical mechanical polishing (CMP) method. Interconnects 105, 105A, a via 113, and a dummy via 106 are formed by the above steps.

Then, as shown in FIG. 10C, a liner insulating film 107, made of, for example, SiCN, is deposited over the first interlayer insulating film 101 and the interconnects 105, 105A.

Then, as shown in FIG. 10D, a resist pattern 108 is formed on the liner insulating film 107 by a lithography method. The resist pattern 108 has an opening pattern which enables only the regions between the interconnects 105 and the regions between the interconnects 105 and 105A in the first interlayer insulating film 101 to be removed.

Then, as shown in FIG. 10E, the liner insulating film 107 and the first interlayer insulating film 101 are etched by a dry etching method by using the resist pattern 108 as a mask, thereby forming voids (air gaps) 109 between the interconnects 105, and between the interconnects 105 and 105A. At this time, the voids 109 are formed so that the height of the bottom surfaces of the voids 109 becomes lower than that of the bottom surfaces of the interconnects 105, 105A.

Then, as shown in FIG. 11A, a second interlayer insulating film 115, which has a low coverage ratio and a low embedding property, is deposited over the liner insulating film 107 including the voids 109, by a chemical vapor deposition (CVD) method. Thus, the top part of each void 109 is closed by the second interlayer insulating film 115.

Then, as shown in FIG. 11B, a via hole 115b, which exposes the interconnect 105 formed in the first interlayer insulating film 101, are formed in the second interlayer insulating film 115 by a lithography method and a dry etching method, and then, interconnect grooves 115a connecting to the via hole 115b are selectively formed.

Then, as shown in FIG. 11C, a barrier metal film 104 and a seed layer are sequentially formed on the bottom and wall surfaces of the interconnect grooves 115a in the second interlayer insulating film 115, and on the bottom and wall surfaces of the via hole 115b. Then, a conductive film, made of copper, is embedded in the interconnect grooves 115a having the barrier metal film 104 and the seed layer formed therein. Then, an excess copper film, remaining on the second interlayer insulating film 115, is removed by a CMP method.

Interconnects 105 and a via 113 are formed in the second interlayer insulating film 115 by the above steps. It should be understood that, although not shown in the figures, it is desirable to form a dummy via under each interconnect, for which a void is to be formed on the most part of its side surfaces in a later step.

A multilayer interconnect structure having an arbitrary number of layers can be formed by sequentially repeating the steps described above.

According to the manufacturing method of the semiconductor device of the first example embodiment, even if the damage layer 101A is formed at the bottoms of the interconnect grooves 101a during formation of the interconnect grooves 101a in FIG. 10A, and during formation of the barrier metal film 104 in the interconnect grooves 101a in FIG. 10B, the interconnects 105A do not peel off from the first interlayer insulating film 101 when forming the voids 109 in FIG. 10E. This is because the dummy via 106 is provided so as to connect to the interconnect 105A, for which the void 109 is to be formed on the most part of its side surfaces.

More specifically, since the dummy via 106 is formed under the interconnect 105A, for which the void 109 is to be formed on the most part of its side surfaces, no damage layer 101A is formed in the region where the dummy via 106 is formed. Moreover, since the dummy via 106 is structured like a stake driven in the first interlayer insulating film 101, the friction between the dummy via 106 and the first interlayer insulating film 101 can prevent the interconnect 105A from peeling off from the first interlayer insulating film 101.

Moreover, since the voids 109 are formed so that the height of the bottom surfaces of the voids 109 becomes lower than that of the bottom surfaces of the interconnects 105, 105A which are in contact with the voids, the capacitance between the interconnects 105, 105A is further reduced.

Note that the manufacturing method of the semiconductor device of the first example embodiment was described with respect to a method of forming the interconnects 105, 105A, the via 113, and the dummy via 106 by a dual damascene method. However, the interconnects 105, 105A, the via 113, and the dummy via 106 may be formed by a damascene method, instead of the dual damascene method.

Moreover, although a conductive film, made of copper, was used as the dummy via 106, other conductive films may be used instead of copper. Examples of other conductive films include Al, Ag, Au, W, Ti, Ta, Mn, Sn, In, Co, Ni, Fe, and the like.

In the case where the dummy via 106 is formed by a damascene method, an insulating film, which has a high adhesion property to an interlayer insulating film in which the dummy via 106 is to be formed (i.e., which has large frictional force with the interlayer insulating film), can be used for the dummy via 106. In this case, an insulating film having a higher adhesion property to the interlayer insulating film is more desirable. An example of an insulating film having a high adhesion property to the dummy via 106 includes a nitride film such as SiN or SiCN. Insulating films made of these nitrides have an effect of having a higher adhesion property to the interconnects 105, 105A than that of a low-k (low dielectric constant) film, in addition to an effect of functioning as a layer for preventing copper diffusion from the interconnects 105, 105A.

As described in the modifications of the first example embodiment, forming a plurality of dummy vias 106 under a single interconnect 105A, forming a long dummy via 106 along the bottom surface of an interconnect 105A, forming a tall dummy via 106 (so as to be in contact with an interconnect in a lower layer), modifying the shape of the side surface of a dummy interconnect in the manner shown in FIGS. 4 and 5, and forming a dummy via 106 in a bent portion 105b of an interconnect 105, can be implemented by a method similar to the manufacturing method of the semiconductor device of the first example embodiment, by changing etching conditions and the like.

Especially, a dummy via 106, whose side surface has a concavo-convex shape as shown in FIG. 4, can be formed by first forming a multilayer insulating film 111 as an interlayer insulating film, then forming a dummy via hole in the formed multilayer insulating film 111, and then, embedding the dummy via hole. More specifically, as an interlayer insulating film of a level at which the dummy via 106 is formed (the “interlayer insulating film of a level at which the dummy via 106 is formed” herein refers to a portion of an interlayer insulating film, which is located in a region located higher than the position of the lower end of the dummy via, and lower than the position of the upper end thereof), the multilayer insulating film 111 is formed by alternately depositing a low-k film, such as a SiOC film or an insulating film having a high pore ratio, and an insulating film made of silicon nitride or the like, to form, for example, SiOC/SiN/SiOC/SiN. Then, a dummy via hole is formed in the multilayer insulating film 111. The dummy via hole is herein formed by an isotropic etching process, such as cleaning, which is performed after an anisotropic etching process. The etching speed of the isotropic etching process varies depending on the kinds of insulating films. In general, the etching speed of a low-k film is higher than that of a silicon nitride film. Because of the difference in etching speed between the insulating films of the multilayer insulating film 111, a layer having a higher etching speed is etched deeper in the lateral direction than a layer having a lower etching speed. A dummy via hole, whose side wall has a concavo-convex shape, can be formed by alternately forming different kinds of insulating films, exhibiting a high etching rate (a high etching-speed ratio), as the interlayer insulating film of a level at which the dummy via 106 is formed. Then, a conductive film or an insulating film is embedded in the dummy via hole, whereby the dummy via 106 can be formed. The interlayer insulating film of a level at which the dummy via 106 is formed need only be formed by a plurality of layers having a high etching speed and a low etching speed, and these layers need not necessarily be formed alternately. In the above description, a silicon nitride film was used as an insulating film which is vertically interposed between low-k films. However, a silicon nitride film further containing carbon may be used as this insulating film. A dummy via, which has a smaller diameter at its lower end than at its upper end, can be formed by forming an insulating film of a two-layer structure, i.e., by forming an insulating film having a high etching speed as an upper layer, and an insulating film having a low etching speed as a lower layer, and by using this insulating film of the two-layer structure as the interlayer insulating film of a level at which the dummy via 106 is formed. Moreover, a dummy via, which has a larger diameter in its lower end than in its upper end, can be formed by forming an insulating film of a two-layer structure, i.e., by forming an insulating film having a low etching speed as an upper layer, and an insulating film having a high etching speed as a lower layer, and by using this insulating film of the two-layer structure as the interlayer insulating film of a level at which the dummy via 106 is formed. Moreover, a dummy via 106, which is shaped so as to have a smaller diameter in its lower and upper ends than in its intermediate part as shown in FIG. 5, can be formed by using a film, which is made of two layers having different etching speeds from each other, as the interlayer insulating film of a level at which the dummy via 106 is formed, as described in FIG. 4, and by performing an etching process under such etching conditions that the dummy via 106 has a bowed shape. The above methods of producing the dummy via 106 apply also to a manufacturing method of a semiconductor device according to a second example embodiment described below.

As described above, in the semiconductor device having a multilayer interconnect structure, in which the voids 109 are formed between the copper interconnects 105, 105A, providing the voids 109 between the copper interconnects 105, 105A can improve the yield of semiconductor devices capable of reducing the capacitance between adjacent interconnects.

### Second Example Embodiment

A second example embodiment will be described below with reference to the drawings.

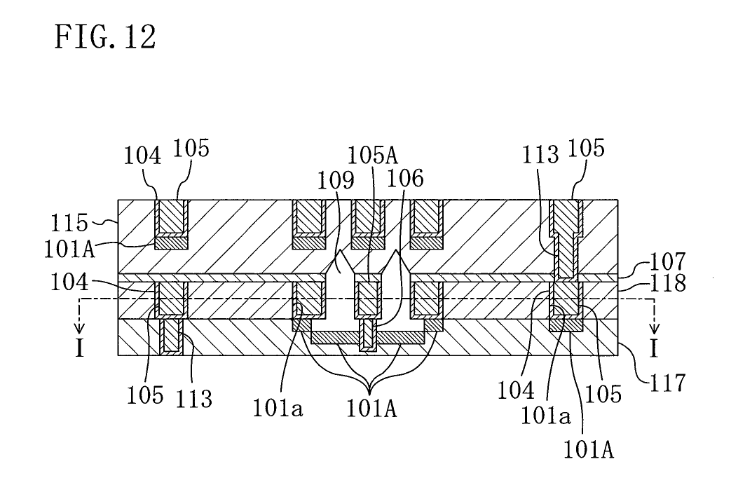

FIG. 12 shows a semiconductor device according to the second example embodiment, and shows a sectional structure corresponding to a cross section taken along line I-I in FIG. 1.

The semiconductor device of the second example embodiment is different from that of the first example embodiment in that an interlayer insulating film of a level at which a dummy via 106 is formed, and an interlayer insulating film of a level at which an interconnect 105A connecting to the dummy via 106 is formed, are made of different insulating films from each other.

It is herein assumed that, as shown in FIG. 12, a third interlayer insulating film 117 is an interlayer insulating film of a level at which a dummy via or a via is formed, and a fourth interlayer insulating film 118 is an interlayer insulating film of a level at which an interconnect is formed. The “level of the interlayer insulating film” herein refers to a space in which a via, a dummy via, and an interconnect are included in the range from the height of the lower surface to the height of the upper surface of the interlayer insulating film. It is preferable to use a low-k film as the fourth interlayer insulating film 118. This is because the use of a low-k film as the fourth interlayer insulating film 118 can reduce the capacitance between interconnects, even when the gap between interconnects 105 is relatively large, and thus, no void 109 was able to be formed in order to ensure the mechanical strength of the interconnect structure.

Moreover, it is preferable to use an insulating film having a small amount of pores and having high mechanical strength, as the third interlayer insulating film 117. In this case, a damage layer 101A is less likely to be formed at the bottom of the interconnect grooves 101a, and even if the damage layer 101A is formed, large friction between the dummy via 106 and the third interlayer insulating film 117 can more reliably prevent the interconnect 105A from peeling off from the third interlayer insulating film 117, as compared to the first example embodiment.

It is desirable to use an insulating film having a relatively low dielectric constant, for example, a SiOC film having pores introduced therein, or an organic insulating film, such as SiLK (registered trademark), FLARE (registered trademark), FSG, polyimide, or benzo-cyclo-butene (BCB), or fluoro-hydrocarbon, or the like, as the fourth insulating film 118. However, the present disclosure is not limited to these insulating materials.

For example, a SiO₂ film or the like can be used as the third interlayer insulating film 117. However, the present disclosure is not limited to the SiO₂ film.

The third interlayer insulating film 117, in which the dummy via 106 is formed, and the fourth interlayer insulating film 118, in which an interconnect 105A connected to the dummy via 106 is formed, are not limited to the above two-layer structure, but may have a multilayer structure of three or more layers. For example, an optimal multilayer interconnect structure can be selected by considering both the mechanical strength in the interconnect structure and reduction in capacitance between interconnects.

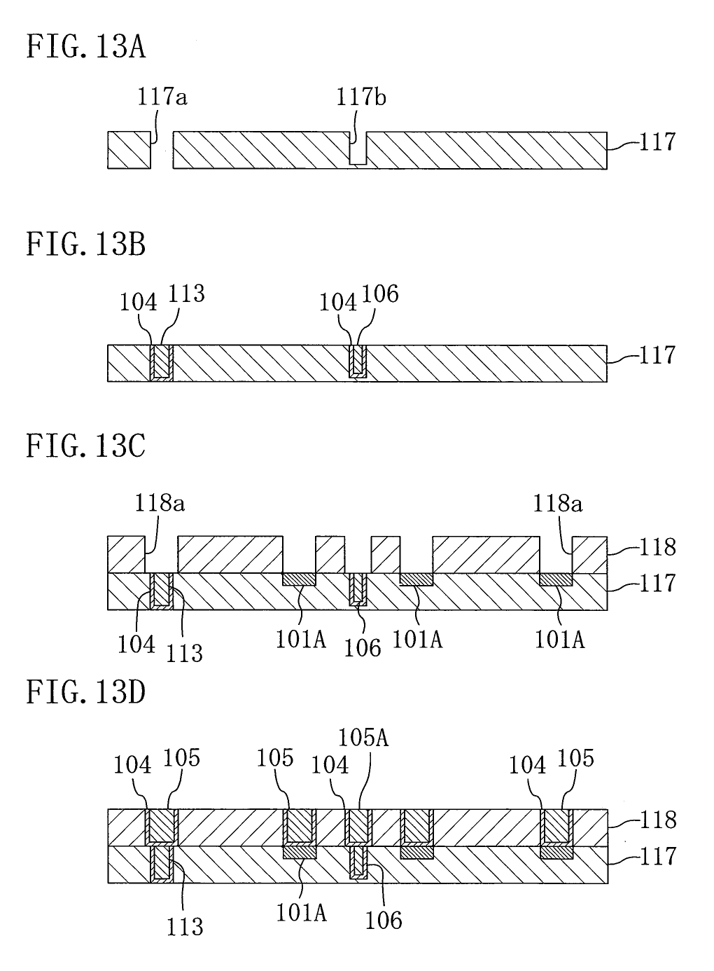

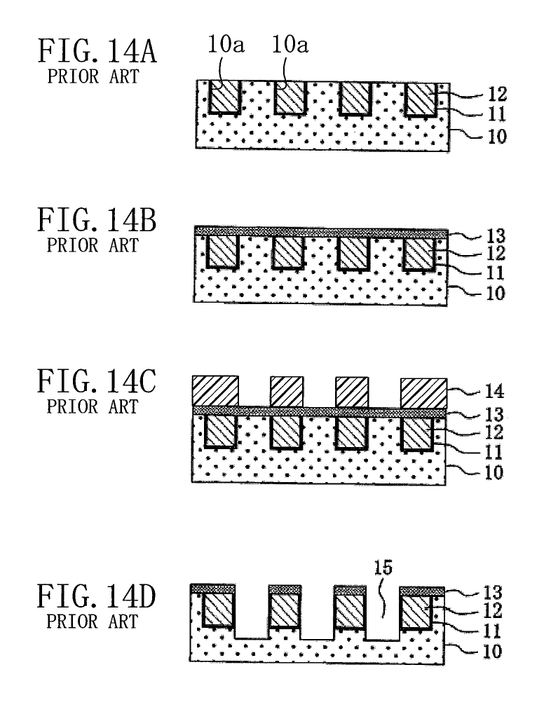

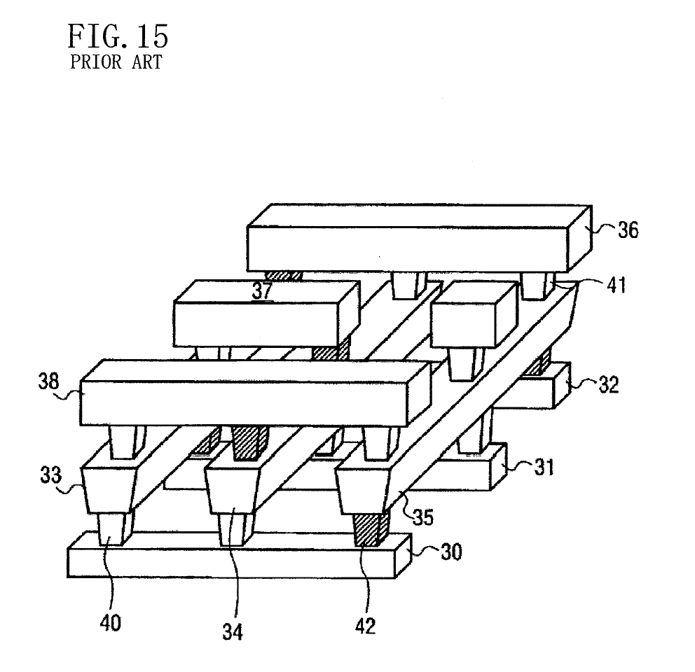

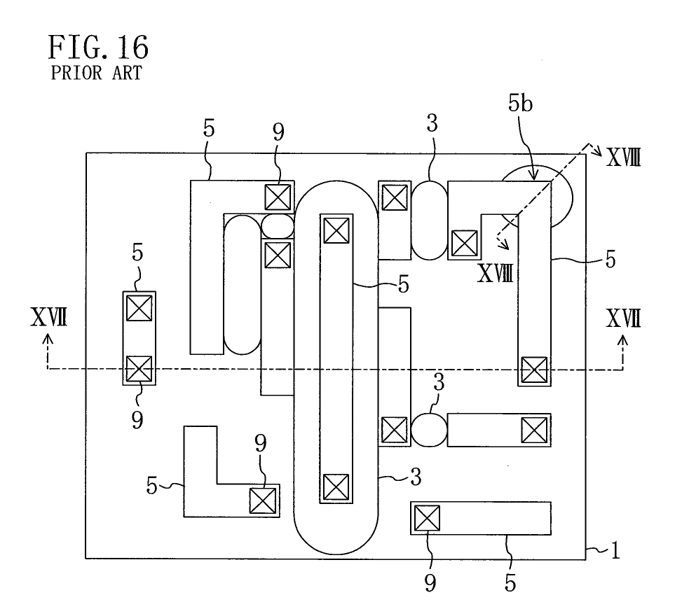

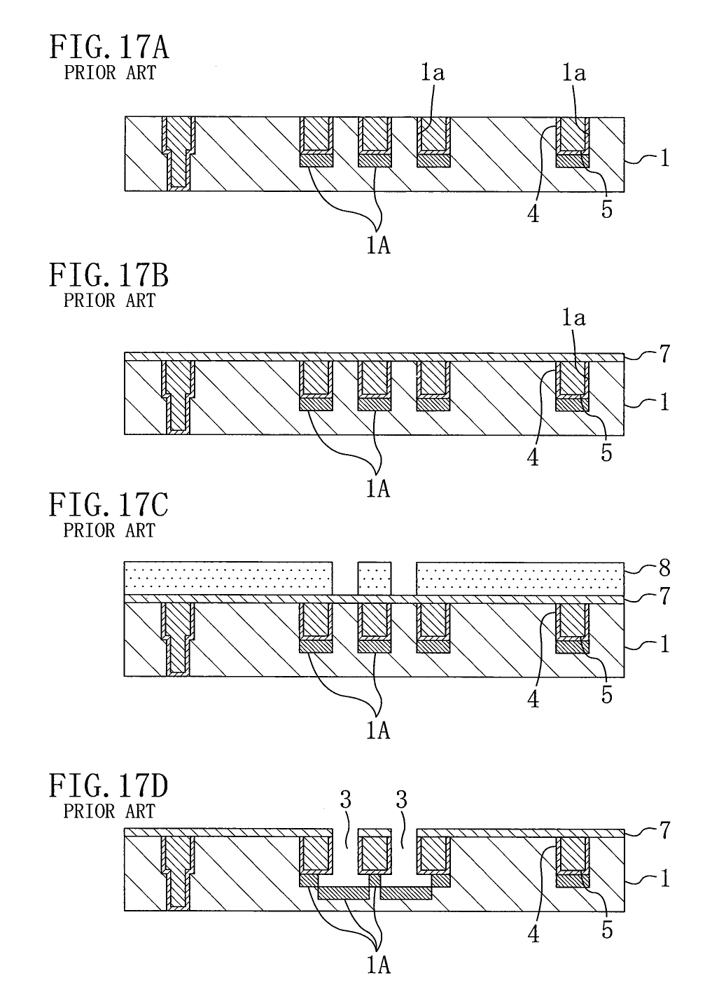

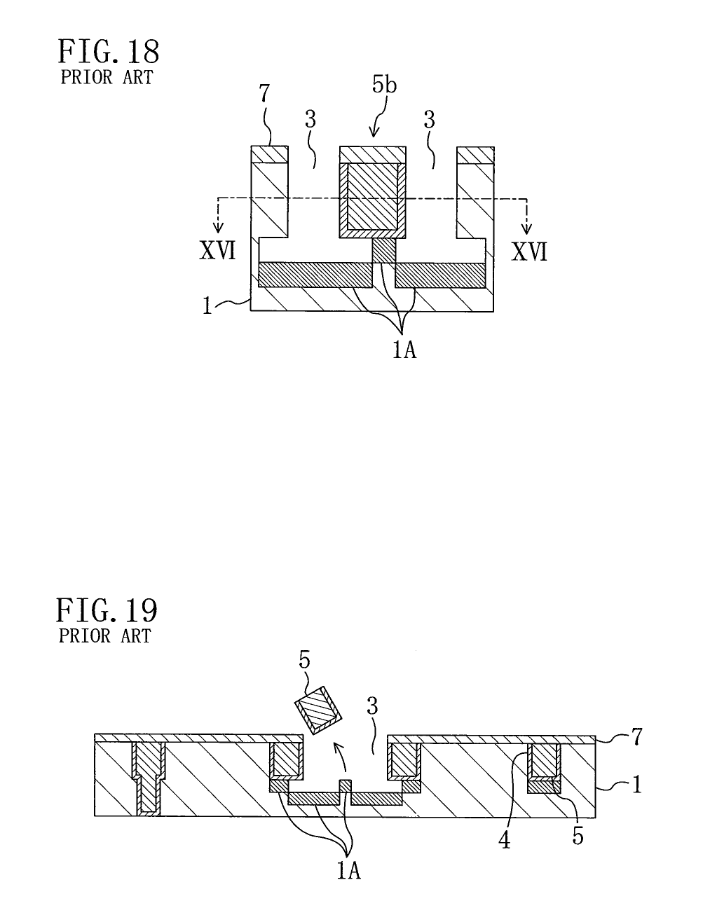

A manufacturing method of the semiconductor device according to the second example embodiment will be described below with reference to FIGS. 13A through 13D.

First, as shown in FIG. 13A, a third interlayer insulating film 117 is deposited over a semiconductor substrate (not shown). Then, a via hole 117a and a dummy via hole 117b are formed in the third interlayer insulating film 117 by a lithography method and a dry etching method.

Then, as shown in FIG. 13B, a barrier metal film 104 and a seed layer (not shown) are sequentially formed on the bottom and wall surfaces of the via hole 117a and the dummy via hole 117b in the third interlayer insulating film 117. Then, a conductive film, made of copper, is embedded in the via hole 117a and the dummy via hole 117b, which have the barrier metal film 104 and the seed layer formed therein. Then, an excess copper film, remaining on the third interlayer insulating film 117, is removed by a CMP method. A via 113 and a dummy via 106 are formed by the above steps.

Then, as shown in FIG. 13C, a fourth interlayer insulating film 118 is formed on the third interlayer insulating film 117 having the via 113 and the dummy via 106 formed therein. Then, interconnect grooves 118a, which selectively expose the via 113 and the dummy via 106, are formed in the fourth interlayer insulating film 118 by a lithography method and a dry etching method.

Then, as shown in FIG. 13D, a barrier metal film 104 and a seed layer are sequentially formed on the bottom and wall surfaces of the interconnect grooves 118a in the fourth interlayer insulating film 118. Then, a conductive film, made of copper, is embedded in the interconnect grooves 118a which have the barrier metal film 104 and the seed layer formed therein. Then, an excess copper film, remaining on the fourth interlayer insulating film 118, is removed by a CMP method. Interconnects 105, 105A are formed by the above steps.

Then, the steps similar to those of FIGS. 10C through 10E and FIGS. 11A through 11C are performed, whereby the semiconductor device shown in FIG. 12 is obtained.

A multilayer interconnect structure having an arbitrary number of layers is formed by sequentially repeating the steps described above.

The effects described above can be obtained by using insulating films having different compositions from each other, as the third interlayer insulating film 117 of a level at which the dummy via 106 is formed, and the fourth interlayer insulating film 118 of a level at which the interconnect 105A connected to the dummy via 106 is formed.

Moreover, as described above, the interlayer insulating films in which the dummy via 106 and the interconnect 105A connected to the dummy via 106 may be formed as a multilayer structure of three or more layers.

Moreover, the semiconductor device of the second example embodiment was described with respect to a method of forming the via 113, the dummy via 106, and the interconnects 105, 105A by a damascene method. However, the via 113, the dummy via 106, and the interconnects 105, 105A may be formed by a dual damascene method.

Moreover, in the first and second example embodiments, it is desirable that the dummy via 106 be formed so as to connect to an interconnect having the smallest interconnect width, such as the interconnect 105A, among the interconnects having a void 109 formed around the most part of their periphery, that is, among the interconnects which are very likely to peel off from the interlayer insulating film. This is because an interconnect having a smaller interconnect width is more likely to peel off from the interlayer insulating film. On the contrary, it is preferable to form the dummy via 106 under the interconnects which are very likely to peel off from the interlayer insulating film.

Note that, in the first and second example embodiments, it is desirable not to form the via 113, which is connected to the interconnect 105, in the interconnects 105, 105A which are in contact with the void 109. Forming the via in the interconnects 105, 105A which are in contact with the void 109 can cause the via hole and the void 109 to connect to each other due to misalignment which occurs when forming the via hole. However, the above structure can prevent the problem of the via hole and the void 109 connecting to each other (see Japanese Published Patent Application No. 2006-120988).

Moreover, in the first and second example embodiments, it is preferable to form a cap film on top of the interconnects 105, 105A so as to be in contact with the interconnects. Forming the cap film in this manner can prevent current leakage without significantly increasing the interconnect resistance. It is desirable that the cap film be made of Co, Mn, W, Ta, or Ru, or an alloy containing at least one kind of a metal selected from Co, Mn, W, Ta, and Ru, or an oxide of Co, Mn, W, Ta, or Ru, or copper-added silicon nitride (CuSiN), and that the cap film have a conductive property.

The semiconductor device and the manufacturing method thereof according to the present disclosure are capable of preventing an interconnect, which is in contact with a void, from peeling off from an insulating film, and also, are capable of providing a semiconductor device having high mechanical strength and low capacitance between interconnects. The semiconductor device and the manufacturing method thereof according to the present disclosure are especially useful for a semiconductor device having a multilayer interconnect structure and a manufacturing method thereof, and the like.

What is claimed is:

1. A semiconductor device, comprising:
an insulating film formed over a semiconductor substrate;
a plurality of interconnects formed in the insulating film;
a via formed in the insulating film so as to connect to at least one of the plurality of interconnects; and
a dummy via formed in the insulating film so as to connect to at least one of the plurality of interconnects, wherein
a void is selectively formed between adjacent ones of the interconnects in the insulating film,
the dummy via is formed under an interconnect which is in contact with the void, so as to connect to the interconnect, and
the via and the dummy via are surrounded by the insulating film with no void interposed therebetween.

2. The semiconductor device of claim 1, wherein
a height of a bottom surface of the void from the semiconductor substrate is lower than, or equal to, that of a bottom surface of the interconnect which is in contact with the void.

3. The semiconductor device of claim 1, wherein
a width of the interconnect which is in contact with the void is larger than that of an interconnect which is not in contact with the void.

4. The semiconductor device of claim 1, wherein
the interconnect which is in contact with the void has its peripheral surface entirely in contact with the void.

5. The semiconductor device of claim 1, wherein
the interconnect which is in contact with the void has its peripheral surface discontinuously in contact with the void.

6. The semiconductor device of claim 1, wherein
the dummy via is formed so as to connect to an interconnect having a smallest interconnect width among the plurality of interconnects.

7. The semiconductor device of claim 1, wherein
multiple ones of the dummy via are formed in one of the plurality of interconnects.

8. The semiconductor device of claim 1, wherein
the dummy via is formed between two of the via, which are formed spaced apart from each other in one of the plurality of interconnects, so as to have a length substantially corresponding to a gap between the two of the via along the one interconnect.

9. The semiconductor device of claim 1, wherein
the plurality of interconnects have a bent portion which is bent in a direction parallel to the semiconductor substrate, and
the dummy via is formed so as to connect to the bent portion.

10. The semiconductor device of claim 1, wherein
a lower-layer insulating film is formed under the dummy via, and
the dummy via is connected to the lower-layer insulating film.

11. The semiconductor device of claim 1, wherein
a concavo-convex portion is formed on a side surface of the dummy via, and
a level of concaves and convexes of the concavo-convex portion of the dummy via is larger than that of concaves and convexes of a concavo-convex portion formed on a side surface of the via.

12. The semiconductor device of claim 1, wherein
the dummy via has a larger diameter in its lower end than in its upper end.

13. The semiconductor device of claim 1, wherein
the insulating film is a SiOC film.

14. The semiconductor device of claim 1, wherein
the insulating film is a laminated film of a first insulating film and a second insulating film,
the dummy via and the via are formed in the first insulating film, and
the interconnects are formed in the second insulating film.

15. The semiconductor device of claim 14, wherein
the first insulating film is an insulating film having higher mechanical strength than that of the second insulating film.

16. The semiconductor device of claim 14, wherein
the first insulating film is an insulating film having a lower pore ratio than that of the second insulating film.

17. The semiconductor device of claim 14, wherein
the second insulating film is a SiOC film.

18. The semiconductor device of claim 14, wherein
the first insulating film is a film containing silicon oxide, or a film containing silicon nitride.

19. The semiconductor device of claim 1, wherein
the via is connected to an interconnect which is not in contact with the void, among the plurality of interconnects.

20. The semiconductor device of claim 1, further comprising:
a liner film formed on the insulating film so as to be in contact with the insulating film, for preventing diffusion of a metal of the interconnects.

21. The semiconductor device of claim 20, wherein
the liner film is a film containing SiCN.

22. The semiconductor device of claim 1, further comprising:
a cap film formed on the plurality of interconnects so as to be in contact with the interconnects, for preventing current leakage from the interconnects.

23. The semiconductor device of claim 22, wherein
the cap film is made of Co, Mn, W, Ta, or Ru, or an alloy containing at least one kind of a metal selected from Co, Mn, W, Ta, and Ru, or an oxide of Co, Mn, W, Ta, or Ru, or CuSiN, and
the cap film has a conductive property.

24. A method for manufacturing a semiconductor device, comprising the steps of:
(a) forming a first insulating film over a semiconductor substrate;
(b) forming a dummy via hole, a via hole, and a plurality of interconnect grooves connecting to the dummy via hole and the via hole, in the first insulating film;
(c) embedding a conductive film in the plurality of interconnect grooves, the via hole, and the dummy via hole to form a plurality of interconnects, a via, and a dummy via from the conductive film;
(d) selectively removing a region between the interconnects in the first insulating film to form a void between the interconnects; and
(e) forming a second insulating film over the first insulating film so as to cover the plurality of interconnects and the void, wherein
the dummy via is formed so as to connect to an interconnect which is in contact with the void, and the via and the dummy via are surrounded by the first insulating film with no void interposed therebetween.

25. The method of claim 24, wherein
in the step (d), the void is formed so that a height of a bottom surface of the void from the semiconductor substrate becomes lower than that of bottom surfaces of the interconnects.

26. The method of claim 24, wherein
in the step (d), the interconnects are formed so that a width of the interconnect which is in contact with the void is larger than that of an interconnect which is not in contact with the void.

27. The method of claim 24, wherein
in the step (d), the void is formed entirely around an interconnect for which the void is to be formed.

28. The method of claim 24, wherein
in the step (d), the void is formed discontinuously around an interconnect for which the void is to be formed.

29. The method of claim 24, wherein
in the step (c), the dummy via is formed so as to connect to an interconnect having a smallest interconnect width among the plurality of interconnects.

30. The method of claim 24, wherein
in the step (c), multiple ones of the dummy via are formed in one of the plurality of interconnects.

31. The method of claim 24, wherein
in the step (c), the dummy via is formed between two of the via, which are formed spaced apart from each other in one of the plurality of interconnects, so as to have a length substantially corresponding to a gap between the two of the via along the one interconnect.

32. The method of claim 24, wherein
in the step (c), the dummy via is formed so as to connect to a bent portion of the interconnects, which is bent in a direction parallel to the semiconductor substrate.

33. The method of claim 24, wherein
in the step (b), the dummy via hole is formed by an isotropic etching process.
